(19) United States
(12) Patent Application Publication
(10) Pub. No.: US 2025/0349755 A1
(43) Pub. Date: Nov. 13, 2025

(54) SEMICONDUCTOR STRUCTURE AND MANUFACTURING METHOD THEREOF

(71) Applicant: TAIWAN SEMICONDUCTOR MANUFACTURING COMPANY, LTD., Hsinchu (TW)

(72) Inventors: Chien-Cheng WU, Yilan County (TW); Tsung-Hsien LEE, Tainan City (TW)

(73) Assignee: TAIWAN SEMICONDUCTOR MANUFACTURING COMPANY, LTD., Hsinchu (TW)

(21) Appl. No.: 18/662,451

(22) Filed: May 13, 2024

(51) Int. Cl. H01L 23/58; H01L 23/50; H01L 23/522; H01L 23/528

(52) U.S. Cl. CPC H01L 23/585; H01L 23/50; H01L 23/5226; H01L 23/528

(57) ABSTRACT

A method includes forming an interconnect structure over a front-side of a substrate; forming a power rail over a back-side of the substrate, wherein a footprint of the interconnect structure overlaps a footprint of the power rail on the substrate; forming a first seal ring structure over the back-side of the substrate, wherein from a top view, the first seal ring structure surrounds the power rail.

### BACKGROUND

Semiconductor integrated circuit (IC) industry has experienced rapid growth. Technological advances in IC materials and design have produced generations of ICs where each generation has smaller and more complex circuits than the previous generation. However, these advances have increased the complexity of processing and manufacturing ICs and, for these advances to be realized, similar developments in IC processing and manufacturing are needed.

In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling-down also produces a relatively high power dissipation value, which may be addressed by using low power dissipation devices such as complementary metal-oxide-semiconductor (CMOS) devices.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A-1D illustrate schematic views of a semiconductor structure in accordance with some embodiments of the present disclosure.

FIGS. 1E and 1F illustrate schematic cross-sectional views of semiconductor structures in accordance with some embodiments of the present disclosure.

FIGS. 2A-7D illustrate schematic cross-sectional views of intermediate stages in the formation of a semiconductor structure in accordance with some embodiments.

FIG. 8 is a flowchart illustrating a method for semiconductor manufacturing in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. One skilled in the art will realize, however, that the values or ranges recited throughout the description are merely examples, and may be reduced or varied with the down-scaling of the integrated circuits.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Backside power delivery may emerge as a method aimed at reducing the intricacies associated with back-end-of-line (BEOL) design and the manufacturing process. This method can include routing power through the backside of the semiconductive substrate, presented a solution to alleviate the congestion of signal routing and interconnects on the front-side of the semiconductive substrate. By simplifying the layout and enhancing power distribution efficiency, it can address challenges in achieving higher performance and energy efficiency in semiconductor devices. However, this approach may lack of structures designed to protect the backside power delivery system. Therefore, the present disclosure in various embodiments provides a back-side seal ring structure to provide robust protection at the back-side of the semiconductor die, specifically tailored for the backside power rail. This back-side seal ring structure can ensure the integrity and reliability of power delivery from the backside of the semiconductor die, addressing a need for safeguarding against potential damages and enhancing the overall performance of the device.

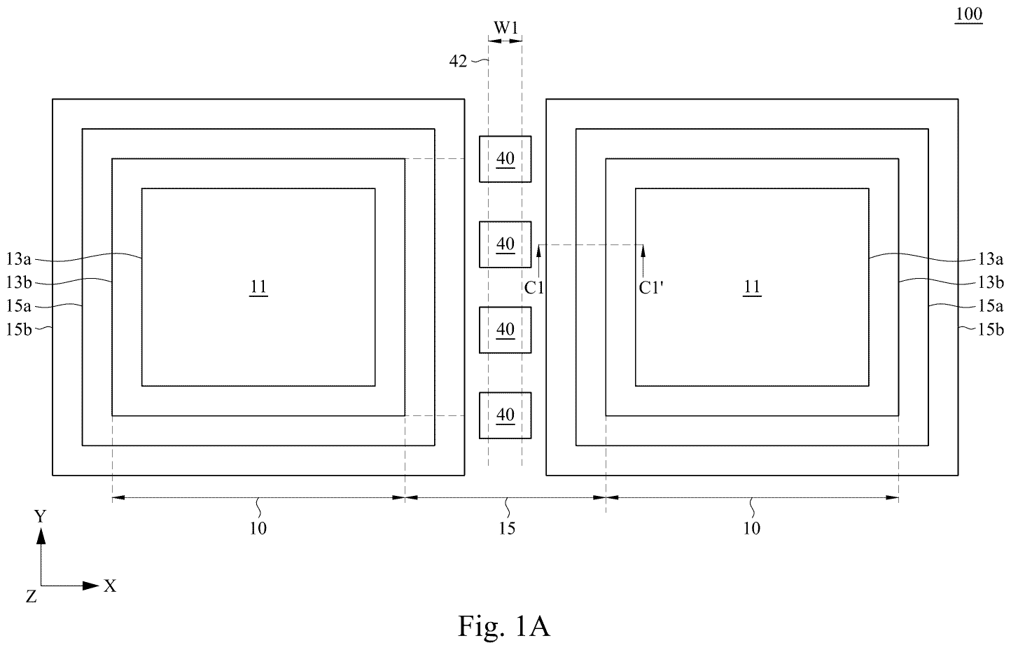

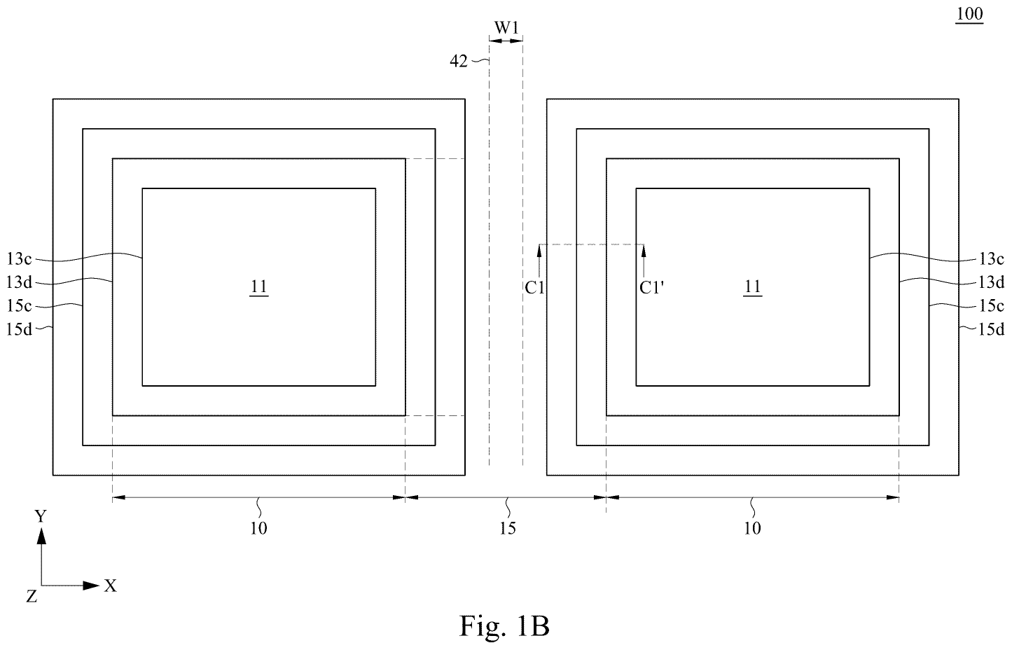

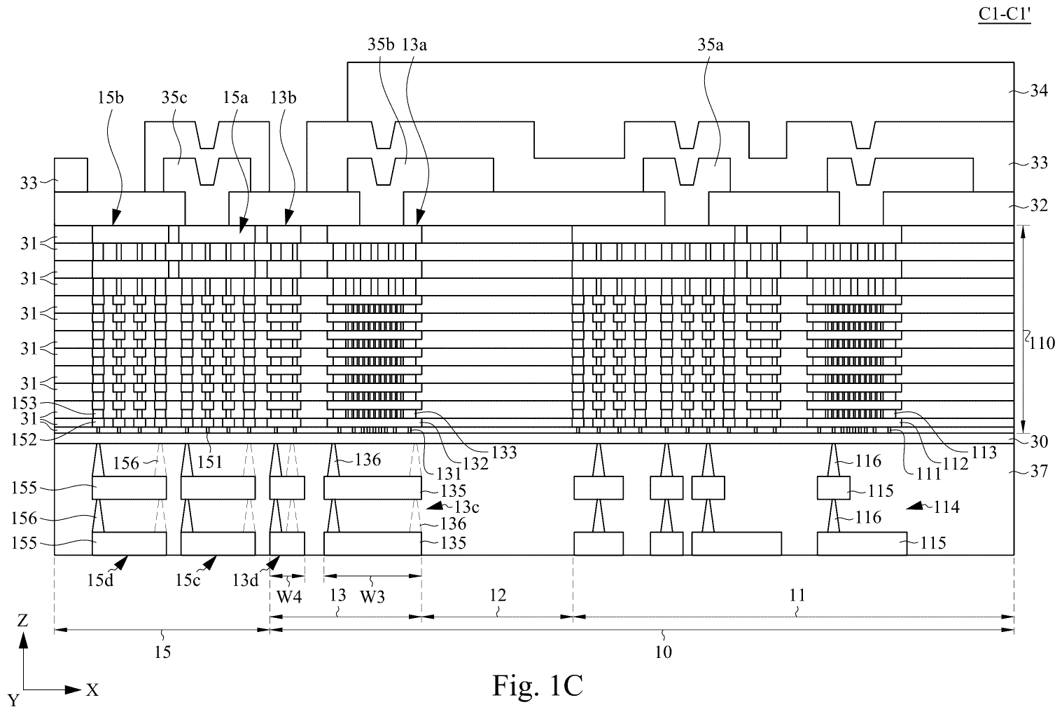

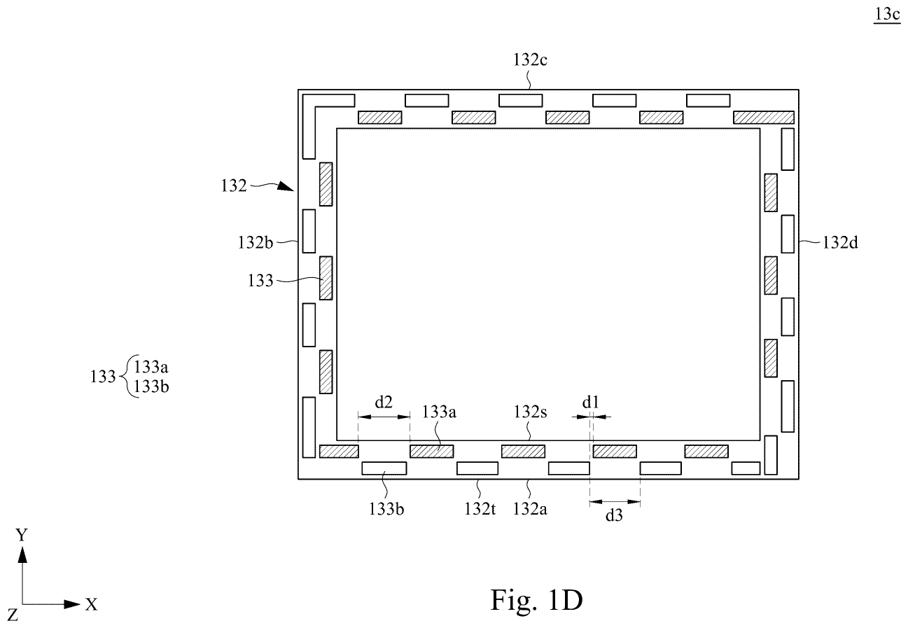

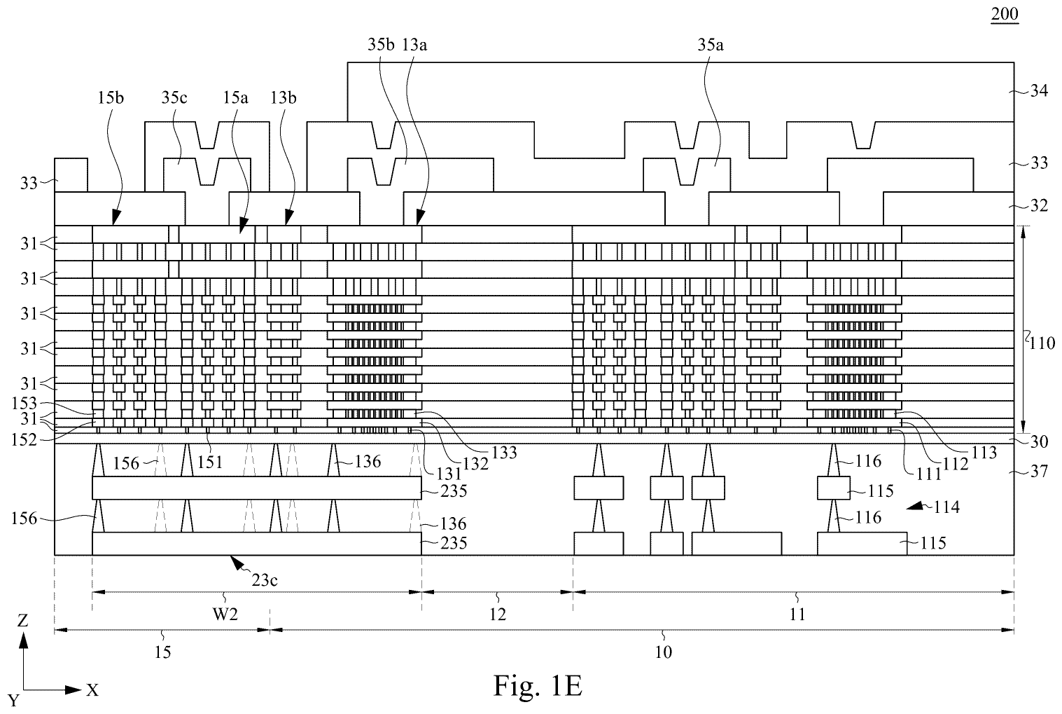

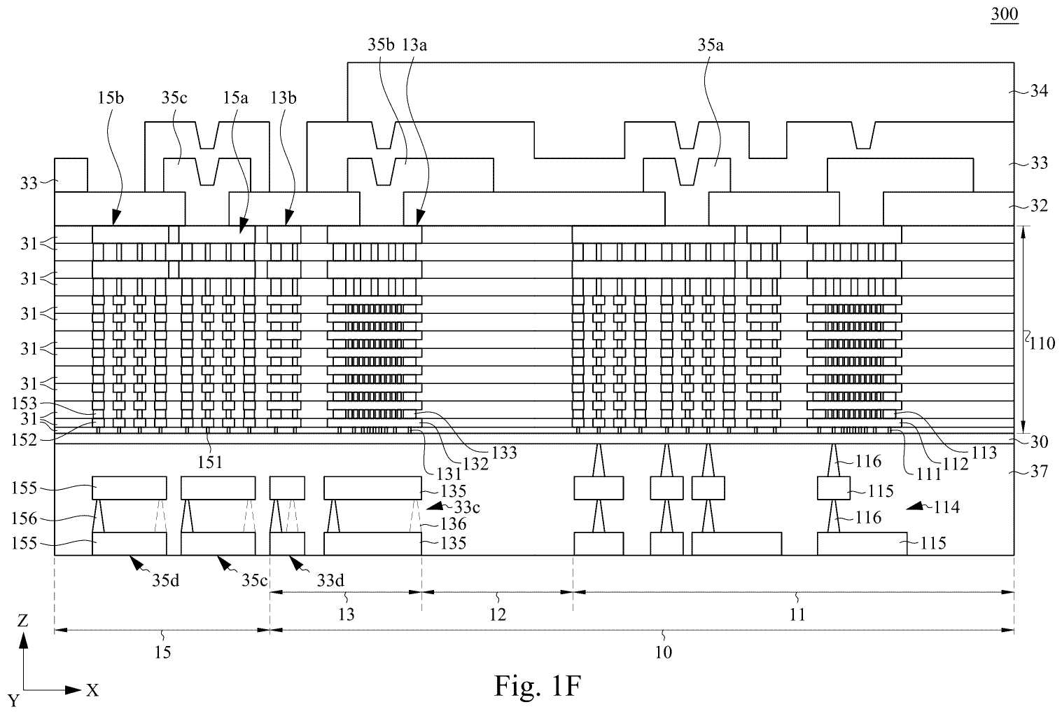

Reference is made to FIGS. 1A-1D. FIG. 1A illustrates a schematic top view of a semiconductor structure 100 including front-side seal ring structures 13a and 13b and front-side dummy patterns 15a and 15b in accordance with some embodiments of the present disclosure. FIG. 1B illustrates a schematic top view of the semiconductor structure 100 including back-side seal ring structures 13c, 13d, 15c, and 15d in accordance with some embodiments of the present disclosure. FIG. 1C illustrates a cross-sectional view obtained from reference cross-sections C1-C1′ in FIGS. 1A and 1B in accordance with some embodiments of the present disclosure. FIG. 1D illustrates a schematic plane view of back-side seal ring structure 13c of the semiconductor structure 100 in accordance with some embodiments of the present disclosure.

As shown in FIGS. 1A-1C, the semiconductor structure 100 can include a chip region 10 and an adjoining scribe line region 15 over a substrate 30 (see FIG. 1C). In some embodiments, the substrate 30 can include a front-end-of-line (FEOL) FEOL structure, which can be the structure prior to the formation of the front-side interconnect structure. Although there is a plurality of the scribe line regions 15, throughout the description, the scribe line region 15 in a singular form can be used to refer to the region between the two illustrated chip regions 10, while all scribe lines may have identical or similar structures. The scribe line region 15 can adjoin the chip regions 10, with one of the scribe line regions 15 between and adjoining both the chip regions 10. The structure as shown in FIGS. 1A and 1B may be a part of a wafer that includes a plurality of chip regions 10 and a plurality of scribe line regions 15. One skilled in the art will realize, however, that the dimensions recited throughout the description are merely examples, and will change if different formation technologies and equipments are used.

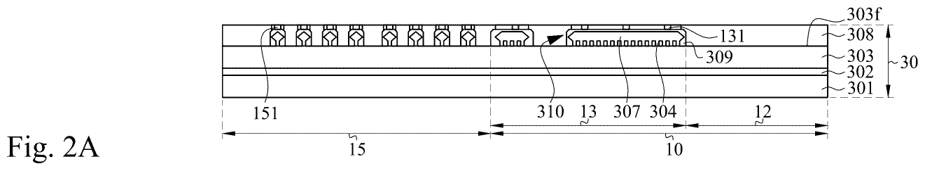

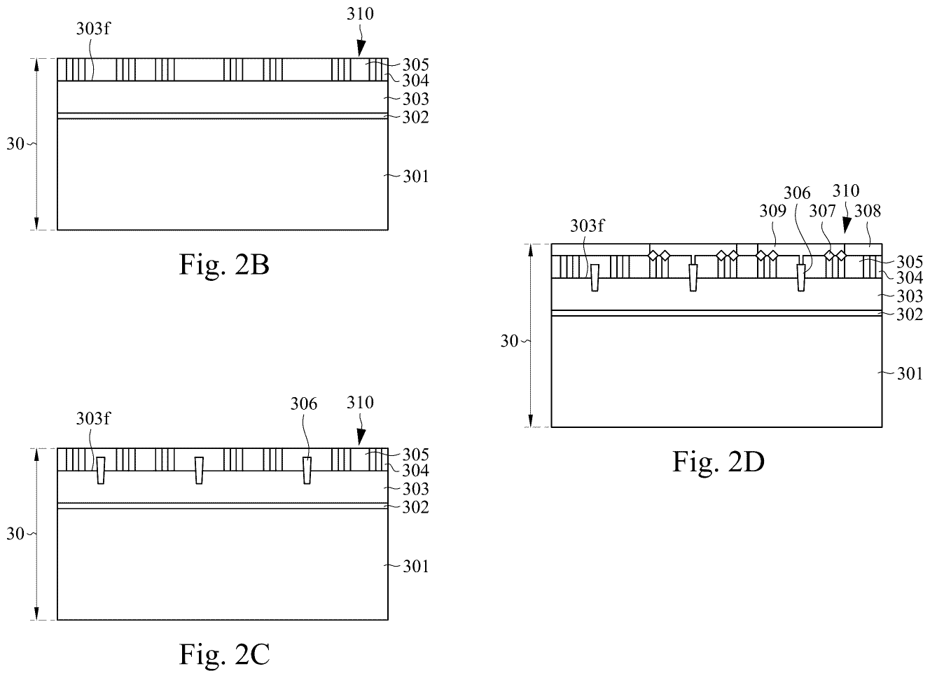

The chip region 10 of the semiconductor structure 100 can include a circuit region 11, an assembly isolation region 12 (see FIG. 1C), a seal ring region 13 (see FIG. 1C). The scribe line region 15 can include front-side dummy patterns 15a and 15b and back-side seal ring structures 15c and 15d. In some embodiments, the front-side seal ring structures 13a and 13b and the front-side dummy patterns 15a and 15b (see FIGS. 1A and 1C) can be ring-shaped profiles from the plane view. The circuit region 11 can include integrated circuits including a variety of electrical devices, such as passive components or active components. The integrated circuits may include logic circuits, memory circuits, analog circuits, digital circuits, and/or the like (not shown). The electrical devices are formed in the substrate 30 and are electrically connected by interconnect structures 110, which are stacked and disposed through inter-metal dielectric (IMD) layers 31, to each other or to another circuitry. In some embodiments, the interconnect structure 110 can include metal lines 112, metal vias 113, and contact plugs 111 connecting source/drain regions in the substrate 30 to the metal lines and vias 112 and 113 in the IMD layers 31. In some embodiments, a power rail 114 can be formed over a back-side of the substrate 30, which in turn reduces routing load and facilitates reduction in cell size. In some embodiments, a footprint of the interconnect structure 110 can overlap a footprint of the power rail 114 on the substrate 30. The power rail 114 can include metal lines 115 and metal vias 116 in an IMD layer 37, and the metal vias 116 can connect the metal lines 114 to the buried power rails 306 (see FIGS. 2C and 2D) in the substrate 30. In some embodiments, the metal via 116 can be also interchangeable referred to as a through silicon via (TSV) slot via.

In some embodiments, the interconnect structures 110 and/or the power rail 114 can include at least one of include aluminum, cobalt, copper, copper alloy, manganese, silicon, titanium, titanium nitride, tantalum, tantalum nitride, tungsten, metal silicide, combinations thereof or other suitable materials. In some embodiments, the interconnect structures 110 can have a carbon atomic concentration greater than about 5%, such as about 5, 10, 15, or 20%. The IMD layers 31 and 37 may be formed of low-k dielectric materials, for example, with k values lower than about 3.0, and even lower than about 2.5. The substrate 30 may include silicon, germanium, group III-group V (also known as III-V) compound semiconductors, and/or other commonly used semiconductor materials. In some embodiments, the metal line 112 can also be changeable referred to as a conductive line and the metal via 113 can also be changeable referred to as a conductive via.

The assembly isolation region 12 (see FIG. 1C) can surround the circuit region 11 with respect to the plan view. In some embodiments, the assembly isolation region 12 can be configured to provide physical and electrical isolation between components in the circuit region 11 and components in the seal ring region 13 (see FIG. 1C). By way of example and not limitation, a width of the assembly isolation region 12 can range from about 3 micrometers (μm) to about 10 μm. If the width of the assembly isolation region 12 is too great, an occupation area of a chip is increased, resulting in a lower production yield, in some instances. If the width is too small, the physical and electric isolation provided to the circuit region 11 is insufficient, in some instances.

The seal ring region 13 can surround the assembly isolation region 12 with respect to the plan view. The seal ring region 13 can include a front-side seal ring structure 13a, a front-side seal ring structure 13b, a back-side seal ring structure 13c, and a back-side seal ring structure 13d, which can be configured to protect circuit region 11 from moisture degradation, ionic contamination and damage during dicing and packaging processes. In some embodiments, footprints of the seal ring structures 13c and 13d can overlap footprints of the seal ring structures 13a and 13b on the substrate 30, respectively. On the other hand, the footprint of the seal ring structure 13c can non-overlap the footprint of the seal ring structure 13b on the substrate 30, and the footprint of the seal ring structure 13d can non-overlap the footprint of the seal ring structure 13a on the substrate 30. In some embodiment, a height of the seal ring structure 13c/13d can be less than a height of the seal ring structure 13a/13b.

In some embodiments, the back-side seal ring structures 13c and 13d (see FIGS. 1B and 1C) can be ring-shaped profiles from the plane view. In some embodiments, the front-side seal ring structures 13a and 13b can be formed simultaneously with the construction of the interconnect structures 110 in circuit region 11, and the back-side seal ring structures 13c and 13d can be formed simultaneously with the construction of the power rail 114 in circuit region 11. Specifically, the front-side seal ring structures 13a and 13b each can include metal lines 132, metal vias 133, and contact plugs 131 connecting source/drain regions in the substrate 30 to the metal lines and vias 132 and 133 in the IMD layers 31. The back-side seal ring structures 13c and 13d each can include metal lines 135 and metal vias 136 in the IMD layers 37 and connecting to the buried power rails 306 (see FIGS. 2C and 2D) in the substrate 30. In some embodiments, the metal via 136 can be also interchangeable referred to as a through silicon via slot via, and the metal line 132/135 can be also interchangeable referred to as a metal layer, or a metal line pattern. In some embodiments, the metal line 135 of the back-side seal ring structure 13c/13d can overlap the metal line 132 of the front-side seal ring structure 13a/13b. By way of example and not limitation, the seal ring structures 13a, 13b, 13c, and 13d can include at least one of include aluminum, copper, copper alloy, titanium, titanium nitride, tantalum, tantalum nitride, tungsten, metal silicide, combinations thereof or other suitable materials. In some embodiments, the back-side seal ring structure 13c can have a width W3 wider than a width W4 of the back-side seal ring structure 13d.

As shown in FIGS. 1A and 1B, the seal ring structure 13a, 13b, 13c, 13d, 15c, 15d, and/or dummy pattern 15a, 15b can have rectangular ring-shaped top view profile. In some embodiment, the seal ring structure 13a, 13b, 13c, and/or 13d can have a ring-shaped top view profile including a curved shape, such as a circular ring-shaped top view profile. In some embodiments, the seal ring structure 13a, 13b, 13c, 13d, 15c, 15d, and/or dummy pattern 15a, 15b can be a close-loop structure. In some embodiments, the seal ring structure 13a, 13b, 13c, 13d, 15c, 15d, and/or dummy pattern 15a, 15b can be a non-close-loop structure. In FIG. 1A, the front-side seal ring structures 13b can encircle the front-side seal ring structures 13a, and the front-side seal ring structures 13a can encircle the interconnect structures 110. In FIG. 1B, the back-side seal ring structure 13d can encircle the back-side seal ring structures 13c, and the back-side seal ring structure 13c can encircle the power rail 114.

As shown in FIG. 1D, the metal line 132 of the back-side seal ring structure 13c can include four segments 132a, 132b, 132c, and 132d. These segments 132a, 132b, 133c, and 133d can be connected in a perpendicular manner, forming a continuous path where the segments 132a and 132c can be aligned parallel to each other along the X direction, while the segments 132b and 132d run parallel along the Y direction. The metal vias 133 can be placed along the metal line 132, adhering to its extension direction. Specifically, on the segment 132a, the vias 133 are categorized into two groups of via 133a and via 133b. These groups can be aligned with the segment's extension, which is along the X direction, but can be distinguished by their proximity to the segment's inner edge 132s (or outer edge 132t). The vias 133a can be positioned closer to the inner edge 132s compared to the vias 133b, effectively placing the vias 133b outwardly relative to the vias 133a. In the other words, the vias 133a can be arranged in a first ring path, and the vias 133b can be arranged in a second ring path different than the first ring path.

Additionally, along the Y axis, the vias 133b do not overlap with the vias 133a, and along the X direction, a distinct dl between the vias 133a and 133b can range from about 0.5 to 5 μm, such as about 0.5, 1, 1.5, 2, 2.5, 3, 3.5, 4, 4.5, or 5 μm. Adjacent two of the vias 133a can be spaced apart by a distance d2 ranging from about 5 to 15 μm, such as about 5, 6, 7, 8, 9, 10, 11, 12, 13, 14, or 15 μm. Adjacent two of the vias 133b can be spaced apart by a distance d3 ranging from about 5 to 15 μm, such as about 5, 6, 7, 8, 9, 10, 11, 12, 13, 14, or 15 μm. In some embodiments, the distances d2 and d3 are greater than the distance d1.

The relationship between the metal vias 133 and the metal line 132 in the back-side seal ring structure 13c, as depicted in FIG. 1D, can exhibit a systematic and/or hierarchical arrangement that can be replicated across various levels within the back-side seal ring structure 13c itself, as well as extended to other back-side seal ring structures, such as seal ring structures 13c, 15c, and 15d within the semiconductor structure 100. Such a coherent and replicable relationship between the metal vias and metal lines within and across the backs-side seal ring structures can enhance the device's overall functionality, making it more robust against physical and environmental stresses.

In some embodiments, the seal ring structure 13a/13b can have a same level height as the interconnect structures 110, and the seal ring structure 13c/13d can have a same level height as the power rail 114. As shown in FIG. 1C, the contact plugs 131 of the front-side seal ring structure 13a/13b can be in the same level height as the contact plugs 111 of the interconnect structures 110, the metal line 132 of the front-side seal ring structure 13a/13b can be in the same level height as the corresponding metal line 112 of the interconnect structures 110, and the metal via 133 of the front-side seal ring structure 13a/13b can be in the same level height as the corresponding metal via 113 of the interconnect structures 110. In some embodiments, the metal line 135 of the back-side seal ring structure 13c/13d can be in the same level height as the corresponding metal line 115 of the power rail 114, and the metal via 136 of the back-side seal ring structure 13c/13d can be in the same level height as the corresponding metal via 116 of the power rail 114.

In some embodiments, the interconnect structures 110 in the circuit region 11 and the front-side seal ring structures 13a and 13b in seal ring region 13 can be rerouted or extended into the assembly isolation region 12 so as to form at least one electrical component in the assembly isolation region 12. In some embodiments, the power rail 114 in the circuit region 11 and the back-side seal ring structures 13c and 13d in seal ring region 13 can be rerouted or extended into the assembly isolation region 12 so as to form at least one electrical component in the assembly isolation region 12. In some embodiments, the seal ring region 13 has more than two or just one seal ring structure in the front-side or in the back-side of the substrate 30. When the seal ring region 13 has multiple seal ring structures, an inner seal ring structure (e.g., front-side seal ring structure 13a and/or front-side seal ring structure 13c) can be configured to couple with the passive components to increase noise immunity and isolation bandwidth for devices in the circuit region 11. In some embodiments, the outer front-side seal rings 13b and 13d may also be referred to as sacrificial seal rings, while the inner front-side seal rings 13a and 13c may also be referred to as main seal rings.

The scribe line region 15 can separate adjacent semiconductor dies to allow for a width of a blade during a sawing process. The scribe line region 15 can define each exposure field on a photomask and each semiconductor die on a wafer. In some embodiments, the scribe line region 15 can includes an exposure field alignment mark for each exposure field, a die alignment mark for each die, and/or a device under test for monitoring manufacturing processes. In some embodiments, the scribe line region 15 can include dummy patterns 15a and 15b and back-side seal ring structures 15c and 15d. The dummy patterns 15a and 15b can surround the seal ring region 13 as shown in FIG. 1A, and the back-side seal ring structures 15c and 15d can surround the seal ring region 13 as shown in FIG. 1B. In some embodiments, the dummy pattern 15a/15b can include dummy bars, virtual bars for line end, virtual bars for corner rounding, dummy pads, and/or other patterns. In some embodiments, the dummy pattern 15a/15b can be interchangeable referred to as a scribe line dummy bar or a seal ring structure. In some embodiments, footprints of the seal ring structures 15c and 15d can overlap footprints of the dummy patterns 15a and 15b on the substrate 30, respectively. On the other hand, the footprint of the seal ring structure 15c can non-overlap the footprint of the dummy pattern 15b on the substrate 30, and the footprint of the seal ring structure 15d can non-overlap the footprint of the dummy pattern 15a on the substrate 30. In some embodiment, a height of the seal ring structure 15c/15d can be less than a height of the dummy pattern 15a/15b.

In some embodiments, structures in dummy pattern 15a/15b can be formed simultaneously with the construction of the interconnect structures 110 in the circuit region 11 using a method such as a dual damascene technique. In some embodiments, the dummy pattern 15a/15b can include metal lines 152, metal vias 153, and contact plugs 151 connecting the substrate 30 to the metal lines and vias 152 and 153 in the IMD layers 31. In some embodiments, structures in back-side seal ring structure 15c/15d can be formed simultaneously with the construction of the power rail 114 in the circuit region 11 using a method such as a dual damascene technique. In some embodiments, the back-side seal ring structure 15c/15d can include metal lines 155 and metal vias 156 in the IMD layers 37 and connecting to the buried power rails 306 (see FIGS. 2C and 2D) in the substrate 30. In some embodiments, the metal via 156 can be also interchangeable referred to as a through silicon via slot via, and the metal line 152/155 can be also interchangeable referred to as a metal layer, or a metal line pattern. In some embodiments, the metal line 155 of the back-side seal ring structure 15c/15d can overlap the metal line 152 of the dummy pattern 15a/15b.

In some embodiments, the dummy pattern 15a/15b can have a same level height as the interconnect structures 110, and the seal ring structure 15c/15d can have a same level height as the power rail 114. As shown in FIG. 1C, the contact plugs 151 of the dummy pattern 15a/15b can be in the same level height as the contact plugs 111 of the interconnect structures 110, the metal line 152 of the dummy pattern 15a/15b can be in the same level height as the corresponding metal line 112 of the interconnect structures 110, and the metal via 153 of the dummy pattern 15a/15b can be in the same level height as the corresponding metal via 113 of the interconnect structures 110. In some embodiments, the dummy pattern 15a/15b can be used to act as a heat spreader. In some embodiments, the scribe line region 15 can free of the interconnect structures. In some embodiments, the metal line 155 of the back-side seal ring structure 15c/15d can be in the same level height as the corresponding metal line 115 of the power rail 114, and the metal via 133 of the back-side seal ring structure 15c/15d can be in the same level height as the corresponding metal via 116 of the power rail 114. In some embodiments, the back-side seal ring structure 15c/15d can be configured to protect circuit region 11 from moisture degradation, ionic contamination and damage during dicing and packaging processes.

In FIG. 1A, one or more test circuits including multiple test pads 40 (commonly referred to as process control monitor pads, or PCM pads) as shown in FIG. 1A can be in the scribe line region 15 to monitor physical characteristics and/or verify electrical features during the manufacturing processes. The test pads 40 may be aligned to a middle line of scribe line region 15. In alternative embodiments, the test pads 40 may not be formed.

During the die sawing process, a laser beam can pass through scribe line region 15, so that the chip regions 10 can be separated from each other. As shown in FIG. 1A, the region between lines 42 can schematically illustrate a possible sawing path, in which the laser beam will be projected. In an exemplary embodiment, the sawing path has a width W1, and the width W1 can equal the single laser spot size of the laser beam or the combined width of multiple laser ablations. The sawing path may cut through the test pads 40, or pass through the spacing between the test pads 40 and the dummy pattern 15a/15b and between the test pads 40 and the back-side seal ring structure 15c/15d. Alternatively, the sawing path my cut through one or all of the dummy patterns 15a and 15b, and the back-side seal ring structures 15c and 15d.

In FIG. 1C, a first passivation layer 32, an optionally second passivation layer 33, and metal pads 35a, 35b, and 35c can be formed over the IMD layers 31. The first passivation layer 32 can be over a topmost IMD layer 31 to protect the underlying interconnect structures and electrical devices from damage and contamination. In some embodiments, the first passivation layer 32 can further provide protection to help prevent or decrease moisture, mechanical, and radiation damage to the underlying electrical devices. The metal pads 35a, 35b, and 35c can be formed to penetrate the first passivation layer 32. The metal pad 35a can connect to the topmost metal line 112 in the interconnect structures 110, the metal pad 35b can connect to the topmost metal line 132 in the front-side seal ring structure 13a, and the metal pad 35c can connect to the topmost metal line 152 in the dummy pattern 15a/15b. In some embodiments, the metal pad 35a, 35b, and/or 35c can be made of aluminum, and thus can also be interchangeable referred to as an aluminum pad.

The second passivation layer 33 can be over the first passivation layer 32 and the metal pads 35a, 35b, and 35c. In some embodiments, the second passivation layer 32 can be configured to protect the metal pads 35a, 35b, and 35c from being damaged. In some embodiments, the second passivation layer 33 can be configured to absorb or release thermal and/or mechanical stress caused during dicing and packaging processes. In some embodiments, the first and second passivation layers 32 and 33 may be formed of oxides, nitrides, and/or combinations thereof, and may be formed of the same or different materials. In some embodiments, a buffer layer 34 can be formed overt the first and second passivation layers 32 and 33. In some embodiments, the buffer layer 34 can be configured to serve as a buffer for a stress mismatch resulted from differences in the coefficients of thermal expansion (CTE) of a semiconductor die and a substrate.

Reference is made to FIGS. 1E and 1F. FIGS. 1E and 1F illustrate schematic cross-sectional views of semiconductor structures 200 and 300 in accordance with some embodiments of the present disclosure. While FIGS. 1E and 1F illustrate embodiments of the semiconductor structures 200 and 300 with different back-side seal ring configurations than the semiconductor structure 100 in FIGS. 1A-1D, the present disclosure may repeat reference numerals and/or letters in the various examples. This repetition is for the purpose of simplicity and clarity and does not in itself dictate a relationship between the various embodiments and/or configurations discussed.

As shown in FIG. 1E, the difference between the embodiment in FIG. 1E and the embodiment in FIGS. 1A-1D is in that the layout of the back-side metal lines 235 in the semiconductor structure 200 can exhibit a continuous extension from the seal ring region 13 into the scribe line region 15. This contrasts with the configuration shown in the semiconductor structure 100, where the back-side of the semiconductor structure 100 features two distinct metal lines 135 and 155, located separately within the seal ring region 13 and the scribe line region 15, respectively, and not forming a continuous line across the seal ring region 13 and the scribe line region 15. Consequently, this continuous layout in the semiconductor structure 200 can allow for the back-side seal ring structure 23c to possess a wider width W2. This width expansion can be the result of the seamless integration of the seal ring region 13 and the scribe line region 15 through the uninterrupted metal line 235. The back-side seal ring structure 23c not only enhances the structural integrity of the semiconductor structure 200 but also potentially improves its functionality by ensuring a more robust mechanical connection across the seal ring region 13 and the scribe line region 15, ensuring the stability and protection of the circuitry against external stresses or damages.

As shown in FIG. 1F, the difference between the embodiment in FIG. 1F and the embodiment in FIGS. 1A-1D is in that the omission of the metal vias 136 and 156 those are closest to the substrate 30 in the semiconductor structure 300. These metal vias 136 and 156, illustrated in FIG. 1C as part of the semiconductor structure 100, can be in establishing a connection between the back-side seal ring structures 13 and 15 and the substrate 30, thereby facilitating an interconnection between the back-side seal ring structures 13c, 13d, 15c, and 15d and the front-side seal ring structures 13a, 13b as well as the front-side dummy patterns 15a and 15b. By omitting the metal vias 136 and 156 in the semiconductor structure 300 closest to the substrate 30, the back-side seal ring structures 33c, 33d, 35c, and 35d can be effectively isolated from the substrate 30. This isolation means that these back-side seal ring structures 33c, 33d, 35c, and 35d may not have a direct electrical or physical connection to both the front-side seal ring structures 13a and 13b and the front-side dummy patterns 15a and 15b located on the front-side of the semiconductor structure 300. The isolation of the back-side seal ring structures 33c, 33d, 35c, and 35d from the substrate 30 and front-side structures can be applied to where independent functionality of the back-side and front-side is desirable.

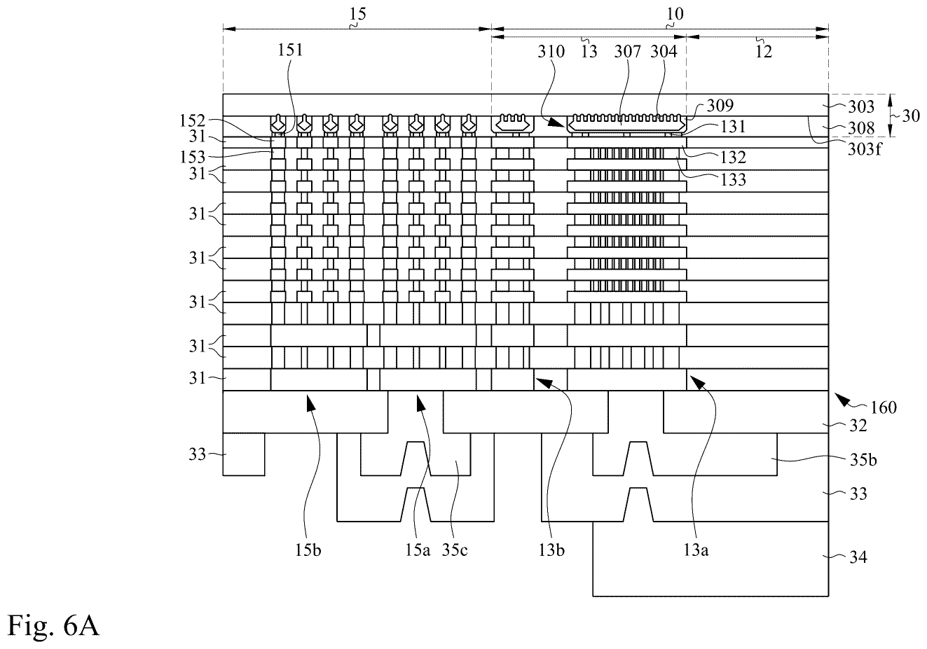

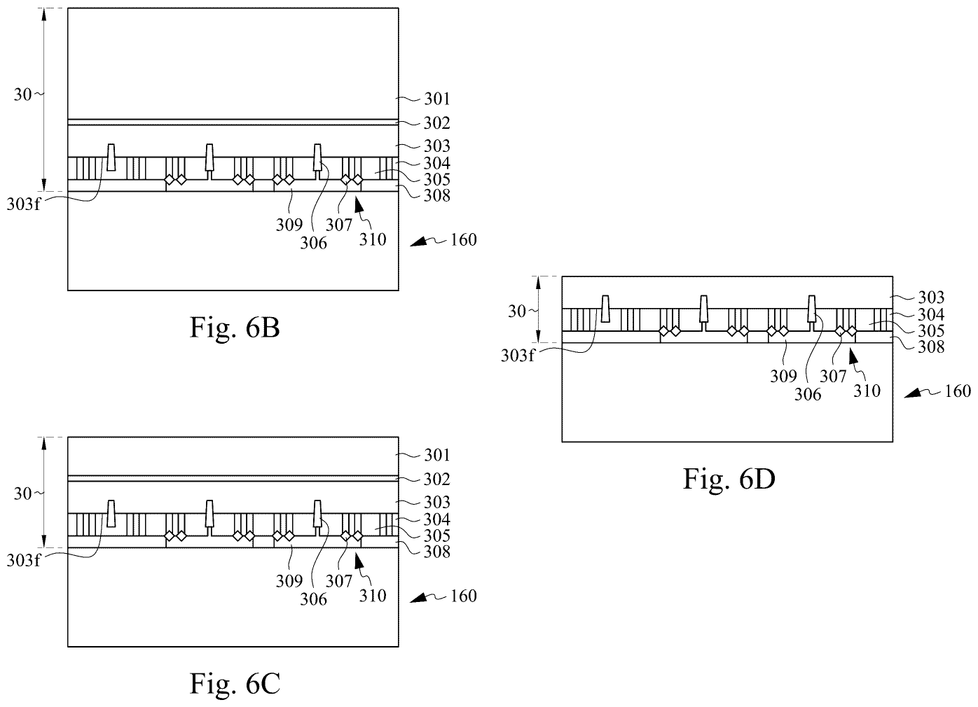

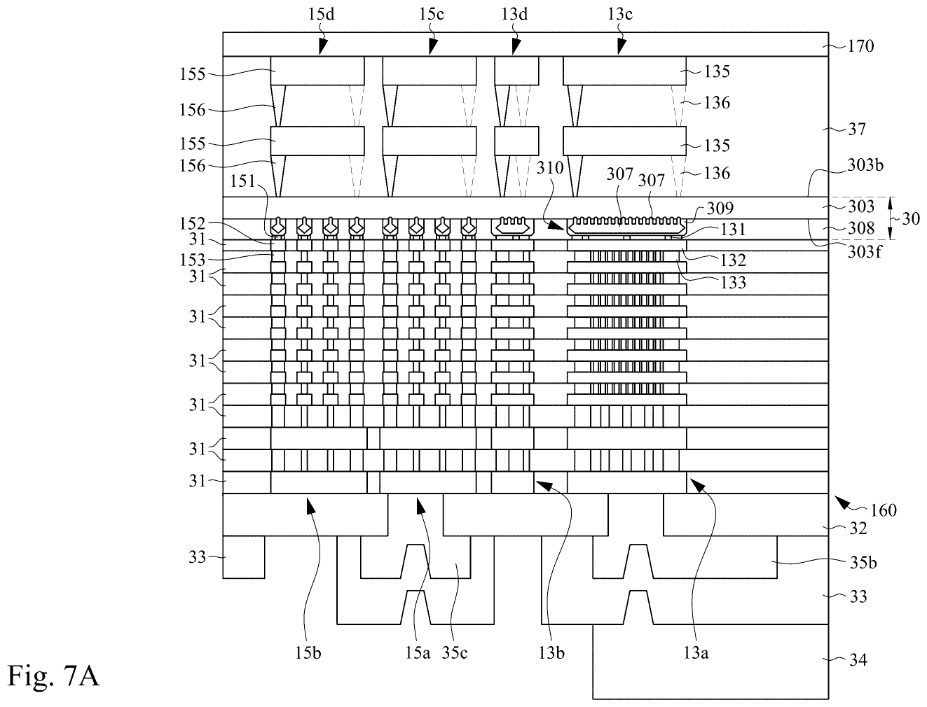

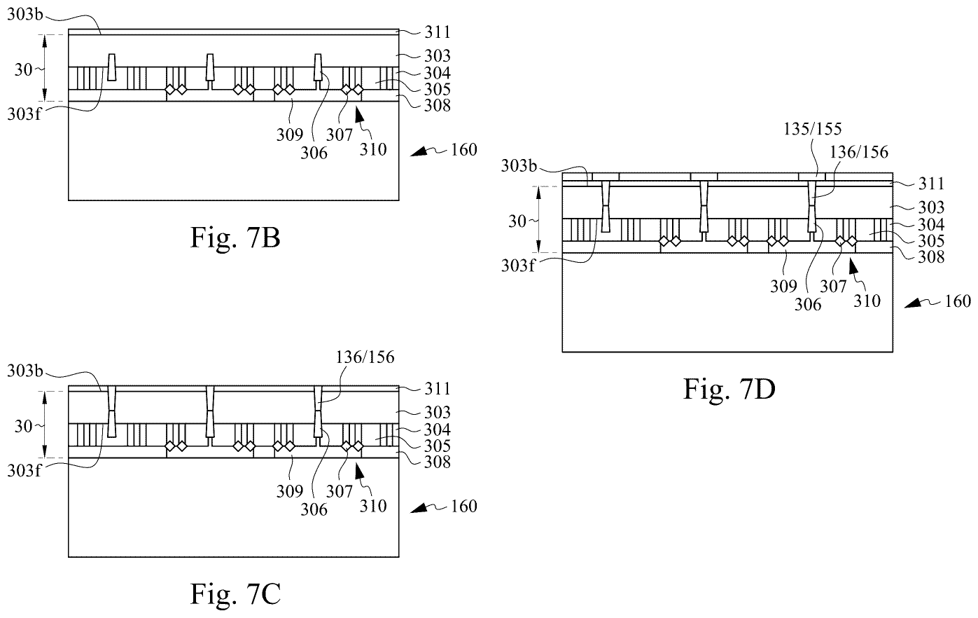

Reference is made to FIGS. 2A-7D. FIGS. 2A-7D illustrate schematic cross-sectional views of intermediate stages in the formation of the semiconductor structure 100 in accordance with some embodiments. FIGS. 2B-2D illustrate further detailed manufacturing processes in FIG. 2A, FIGS. 6B-6D illustrate further detailed manufacturing processes in FIG. 6A, and FIGS. 7B-7D illustrate further detailed manufacturing processes in FIG. 7A. It is understood that additional operations can be provided before, during, and after the processes shown by FIGS. 2A-7D, and some of the operations described below can be replaced or eliminated, for additional embodiments of the method. The order of the operations/processes may be interchangeable. The fabrication method illustrated in FIGS. 2A-7D, while focusing on the seal ring region 13 and the scribe line region 15, represents a comprehensive manufacturing process applicable throughout the semiconductor structure, including areas such as the circuit region 11. This fabrication method can highlight the complex and interconnected nature of semiconductor device manufacturing, ensuring uniform precision and meticulous attention to detail for each component.

Reference is made to FIGS. 2A-2D. The substrate 30 can be formed. The substrate 30 may include a second semiconductive substrate 303 (see FIG. 2B) over a first semiconductive substrate 301 (see FIG. 2B), such as silicon wafer. In some embodiments, a buffer layer 302 (see FIG. 2B) can be formed to sandwich between the first and second semiconductive substrates 301 and 303. The second semiconductive substrate 303 may comprise, for example, bulk silicon, doped or undoped, or an active layer of a semiconductor-on-insulator (SOI) substrate. Generally, an SOI substrate comprises a layer of a semiconductor material, such as silicon, formed on an insulator layer. The insulator layer may be, for example, a buried oxide (BOX) layer or a silicon oxide layer. The insulator layer is provided on a substrate, such as a silicon or glass substrate. Alternatively, the second semiconductive 303 may include another elementary semiconductor, such as germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. Other substrates, such as multi-layered or gradient substrates, may also be used. In some embodiments, the buffer layer 302 may be formed of a dielectric material, such as silicon nitride, silicon oxide, silicon oxynitride, or the like, having a high etching selectivity from the etching of the first and second semiconductive substrates 301 and 303. The buffer layer 302 may be formed by any suitable method, such as CVD, ALD, or the like. In some embodiments, the buffer layer 302 can be an etch stop layer.

In some embodiments, one or more active and/or passive devices 310 are formed on a front-side 303f of the second semiconductive substrate 303 as illustrated in FIGS. 1A and 1B. The one or more active and/or passive devices 310 may include various N-type metal-oxide semiconductor (NMOS) and/or P-type metal-oxide semiconductor (PMOS) devices, such as transistors, capacitors, resistors, diodes, photo-diodes, fuses, and the like. In some embodiments, the device 310 can be electrically connect to a passive device, such as an amplifier, a filter, a memory, and the like. In some embodiments, the one or more active and/or passive devices 310 can have no functionality and be dummy devices in the seal ring region 13 and the scribe line region 15. In the depicted embodiments, the semiconductor devices 310 are fin field-effect transistors (FinFET) that are three-dimensional MOSFET structure formed in fin-like strips of semiconductor protrusions referred to as fins 304. The cross-section shown in FIG. 1A is taken along a direction perpendicular to a longitudinal axis of the fin 304. In some embodiments, the fin 304 can be interchangeably referred to as a channel region, a channel pattern, a fin structure, a fin pattern, or a semiconductor strip. The fin 304 may be formed by patterning the second semiconductive e substrate 303 using photolithography and etching techniques from the front-side of the second semiconductive substrate 303. In some embodiments, the semiconductive substrate 303 may comprise any number of fins. In some other embodiments, the semiconductor devices 310 can be planar transistors, 2D material transistors, or gate-all-around (GAA) transistors.

In some embodiments, shallow trench isolation (STI) regions 305 (see FIGS. 2B-2D) formed on opposing sidewalls of the fin 303 to laterally surround the fin 303. In some embodiments, the STI regions 305 may be formed by depositing one or more dielectric materials (e.g., silicon oxide) to completely fill the trenches around the fins 304 and then recessing the top surface of the dielectric materials. The dielectric materials of the STI regions 305 may be deposited using a high density plasma chemical vapor deposition (HDP-CVD), low-pressure CVD (LPCVD), sub-atmospheric CVD (SACVD), a flowable CVD (FCVD), spin-on, and/or the like, or a combination thereof. After the deposition, an anneal process or a curing process may be performed. In some cases, the STI regions 305 may include a liner such as, for example, a thermal oxide liner grown by oxidizing the silicon surface. The recess process may use, for example, a planarization process (e.g., a chemical mechanical polish (CMP)) followed by a selective etch process (e.g., a wet etch, or dry etch, or a combination thereof) that may recess the top surface of the dielectric materials in the STI region 305 such that an upper portion of fins 304 protrudes from surrounding insulating STI regions 305. In some cases, the patterned hard mask used to form the fins 303 may also be removed by the planarization process.

As shown in FIG. 2C, buried power rails 306 can be formed in the STI regions 305. In some embodiments, the buried power rail 306 may be form by forming a trench extending through the STI region 305 into the second semiconductive substrate 303 from the front-side 303f of the second semiconductive substrate 303. Subsequently, a conductive material is filled in the trench to form the buried power rail 306. The conductive material may include metal, such as tungsten (W), ruthenium (Ru), aluminum (Al), copper (Cu), or other suitable conductive material. In some embodiments, the conductive material may be deposited by CVD, physical vapor deposition (PVD), sputter deposition, or other techniques suitable for depositing conductive materials.

In some embodiments, a gate structure (not shown) of the semiconductor device 310 can be formed to extend across the fins 304. In some embodiments, the gate structure can be a high-k, metal gate (HKMG) gate structure that may be formed using a gate-last process flow. In a gate-last process flow a sacrificial dummy gate structure (not shown) is formed after forming the STI regions 305. The dummy gate structure may comprise a dummy gate dielectric, a dummy gate electrode, and a hard mask. First a dummy gate dielectric material (e.g., silicon oxide, silicon nitride, or the like) may be deposited. Next a dummy gate material (e.g., amorphous silicon, polycrystalline silicon, or the like) may be deposited over the dummy gate dielectric and then planarized (e.g., by CMP). A hard mask layer (e.g., silicon nitride, silicon carbide, or the like) may be formed over the dummy gate material. The dummy gate structure is then formed by patterning the hard mask and transferring that pattern to the dummy gate dielectric and dummy gate material using suitable photolithography and etching techniques. The dummy gate structure may extend along multiple sides of the protruding fins 304 and extend across the fins 304 over the surface of the STI regions 305. As described in greater detail below, the dummy gate structure may be replaced by the gate structure. The materials used to form the dummy gate structure and hard mask may be deposited using any suitable method such as CVD, plasma-enhanced CVD (PECVD), atomic layer deposition (ALD), plasma-enhanced ALD (PEALD) or the like, or by thermal oxidation of the semiconductor surface, or combinations thereof. In some embodiments, the gate structure can be interchangeably referred to as a gate, a functional gate, a gate strip, a gate pattern, or a gate layer.

As shown in FIG. 2C, source/drain regions 307 of the semiconductor device 310 are formed. The source/drain regions 307 can be semiconductor regions in direct contact with the semiconductor fin 304. In some embodiments, the source/drain regions 307 may include heavily-doped regions and relatively lightly-doped drain extensions, or LDD regions. The LDD regions may be formed in the fin 304s, for example, by implanting dopants (e.g., As, P, B, In, or the like) using an ion implantation process. The source/drain regions 307 may include an epitaxially grown region. For example, after forming the LDD regions, the heavily-doped source and drain regions may be formed by first etching the fins to form recesses 304r, and then depositing a crystalline semiconductor material in the recess 304r by a selective epitaxial growth (SEG) process that may fill the recess 304r and may extend further beyond the original surface of the fin 304 to form raised source/drain epitaxy structures. The crystalline semiconductor material may be elemental (e.g., Si, or Ge, or the like), or an alloy (e.g., Si₁₋ₓCₓ, or Si₁₋ₓGeₓ, or the like). The SEG process may use any suitable epitaxial growth method, such as e.g., vapor/solid/liquid phase epitaxy (VPE, SPE, LPE), or metal-organic CVD (MOCVD), or molecular beam epitaxy (MBE), or the like.

In some embodiments, the source/drain region 307 can be interchangeably referred to as a source/drain structure, a source/drain pattern, an epitaxial structure, or an epitaxial pattern. In a semiconductor device such as a transistor, the “source” and “drain” can be referred to two terminals or regions that carry charge carriers (either electrons or holes) into and out of the device. The source is the part of the transistor where the charge carriers come from. In an N-type transistor, the charge carriers are electrons, and in a P-type transistor, the charge carriers are holes. The drain is where the charge carriers go to. The gate is the control terminal for the transistor. By applying a voltage to the gate, the flow of charge carriers from the source to the drain can be controlled. Therefore, the term, “source/drain,” in a semiconductor device refers to the regions where charge carriers are injected (e.g., source) and collected (e.g., drain) for the flow of current controlled by the gate voltage.

Once the source/drain regions 307 are formed, an ILD layer 308 can be deposited over the source/drain regions 307. In some embodiments, a contact etch stop layer (CESL) (not shown) of a suitable dielectric (e.g., silicon nitride, silicon carbide, or the like, or a combination thereof) may be deposited prior to depositing the ILD material. A planarization process (e.g., CMP) may be performed to remove excess ILD material and any remaining hard mask material from over the dummy gates to form a top surface wherein the top surface of the dummy gate material is exposed and may be substantially coplanar with the top surface of the ILD layer 308. The gate structure may then be formed by first removing the dummy gate structure using one or more etching techniques. Next, a replacement gate dielectric layer comprising one more dielectrics, followed by a replacement gate metal layer comprising one or more metals, are deposited to form the gate structure. In some embodiments, the insulating materials to form the ILD layer 308 may comprise silicon oxide, phosphosilicate glass (PSG), borosilicate glass (BSG), boron-doped phosphosilicate glass (BPSG), undoped silicate glass (USG), a low dielectric constant (low-k) dielectric such as, fluorosilicate glass (FSG), silicon oxycarbide (SiOCH), carbon-doped oxide (CDO), flowable oxide, or porous oxides (e.g., xerogels/aerogels), or the like, or a combination thereof. The dielectric materials used to form the ILD layer 308 may be deposited using any suitable method, such as CVD, physical vapor deposition (PVD), ALD, PEALD, PECVD, SACVD, FCVD, spin-on, and/or the like, or a combination thereof.

The gate dielectric layer includes, for example, a high-k dielectric material such as oxides and/or silicates of metals (e.g., oxides and/or silicates of Hf, Al, Zr, La, Mg, Ba, Ti, and other metals), silicon nitride, silicon oxide, and the like, or combinations thereof, or multilayers thereof. In some embodiments, the gate metal layer may be a multilayered metal gate stack comprising a barrier layer, a work function layer, and a gate-fill layer formed successively on top of gate dielectric layer. Example materials for a barrier layer include TiN, TaN, Ti, Ta, or the like, or a multilayered combination thereof. A work function layer may include TiN, TaN, Ru, Mo, Al, for a p-type FET, and Ti, Ag, TaAl, TaAlC, TiAlN, TaC, TaCN, TaSiN, Mn, Zr, for an n-type FET. Other suitable work function materials, or combinations, or multilayers thereof may be used. The gate-fill layer which fills the remainder of the recess may comprise metals such as Cu, Al, W, Co, Ru, or the like, or combinations thereof, or multi-layers thereof. The materials used in forming the gate structure may be deposited by any suitable method, e.g., CVD, PECVD, PVD, ALD, PEALD, electrochemical plating (ECP), electroless plating and/or the like.

As shown in FIG. 2D, contacts 309 can be formed to electrically couple the overlying front-side interconnect structures 110 (see FIG. 1C) to the semiconductor device devices 310 through the source/drain regions 307. The contacts 309 may be formed using photolithography, etching and deposition techniques. For example, a patterned mask may be formed over the ILD layer 308 and used to etch openings that extend through the ILD layer 308 to expose the gate structure as well as the source/drain regions 307. Thereafter, conductive liner may be formed in the openings in the ILD layer 308. Subsequently, the openings are filled with a conductive fill material. The liner comprises barrier metals used to reduce out-diffusion of conductive materials from the contacts 309 into the surrounding dielectric materials. In some embodiments, the liner may comprise two barrier metal layers. The first barrier metal comes in contact with the semiconductor material in the source/drain regions 307 and may be subsequently chemically reacted with the heavily-doped semiconductor in the source/drain regions 307 to form a low resistance ohmic contact, after which the unreacted metal may be removed. For example, if the heavily-doped semiconductor in the source/drain regions 307 is silicon or silicon-germanium alloy semiconductor, the first barrier metal may comprise Ti, Ni, Pt, Co, other suitable metals, or their alloys, and may form silicide with the source/drain regions 307. The second barrier metal layer of the conductive liner may additionally include other metals (e.g., TiN, TaN, Ta, or other suitable metals, or their alloys). A conductive fill material (e.g., W, Al, Cu, Ru, Ni, Co, alloys of these, combinations thereof, and the like) may be deposited over the conductive liner layer to fill the contact openings, using any acceptable deposition technique (e.g., CVD, ALD, PEALD, PECVD, PVD, ECP, electroless plating, or the like, or any combination thereof). Next, a planarization process (e.g., CMP) may be used to remove excess portions of all the conductive materials from over the surface of the ILD layer 308. The resulting conductive layer extend into the ILD layer 308 and constitute contacts 309 making physical and electrical connections to the electrodes of electronic devices, such as the semiconductor device 304. In some embodiments, the contact 309 can be interchangeably referred to as a source/drain contact or a source/drain plug.

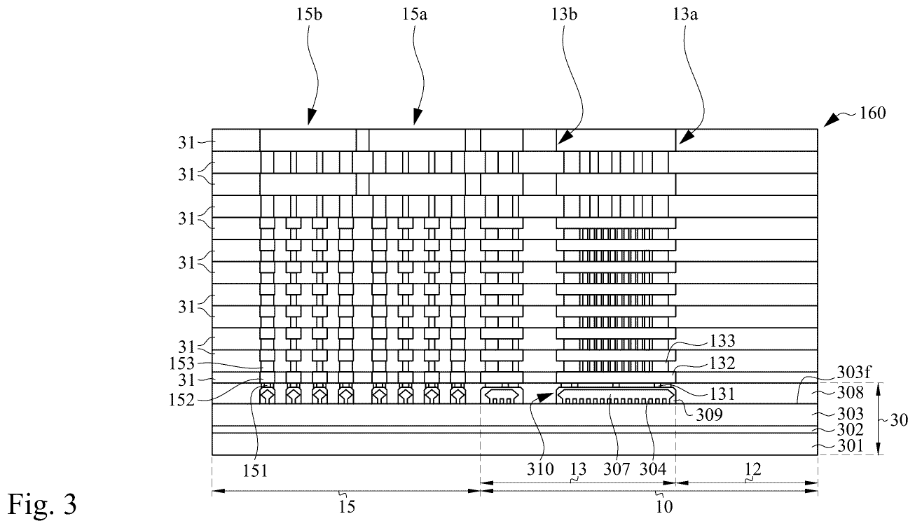

Reference is made to FIG. 3. A back end of line (BEOL) structure 160 can be formed over the substrate 30 within the chip region 10 including the circuit region 11 and the seal ring region 13 and the scribe line region 15. A BEOL structure 160 can include the interconnect structure 110 (see FIG. 1C) within the circuit region 11, the front-side seal ring structures 13a and 13b within the seal ring region 13, and the dummy patterns 15a and 15b within the scribe line region 15. The devices 310 formed in the substrate 30 can be electrically connected by the interconnect structures 110 (see FIG. 1C), which are stacked and disposed through inter-metal dielectric (IMD) layers 31, to each other or to another circuitry. As shown in FIG. 1C, the interconnect structure 110 can include metal lines 112, metal vias 113, and contact plugs 111 connecting the substrate 30 to the metal lines and vias 112 and 113 in the IMD layers 31. In some embodiments, the contact plugs 111 may connect the overlying metal lines and vias 112 and 113 to source/drain regions 307 in the substrate 30.

In some embodiments, the front-side seal ring structures 13a and 13b can be formed using a method such as a dual damascene technique and simultaneously with the construction of the interconnect structures 110 (see FIG. 1C) in circuit region 11. The front-side seal ring structures 13a and 13b each can include metal lines 132, metal vias 133, and contact plugs 131 connecting the substrate 30 to the metal lines and vias 132 and 133 in the IMD layers 31. The contact plugs 131 may connect the overlying metal lines and vias 132 and 133 to source/drain regions 307 in the substrate 30. In some embodiments, the front-side dummy patterns 15a and 15b can be formed using a method such as a dual damascene technique and simultaneously with the construction of the interconnect structures 110 (see FIG. 1C) in circuit region 11. The front-side dummy patterns 15a and 15b each can include metal lines 152, metal vias 153, and contact plugs 151 connecting the substrate 30 to the metal lines and vias 152 and 153 in the IMD layers 31. The contact plugs 151 may connect the overlying metal lines and vias 152 and 153 to source/drain regions 307 in the substrate 30. In some embodiments, the seal ring structures 13a and 13b and front-side dummy patterns 15a and 15b can include at least one of include aluminum, carbon, cobalt, copper, copper alloy, manganese titanium, titanium nitride, tantalum, tantalum nitride, silicon, tungsten, metal silicide, combinations thereof or other suitable materials.

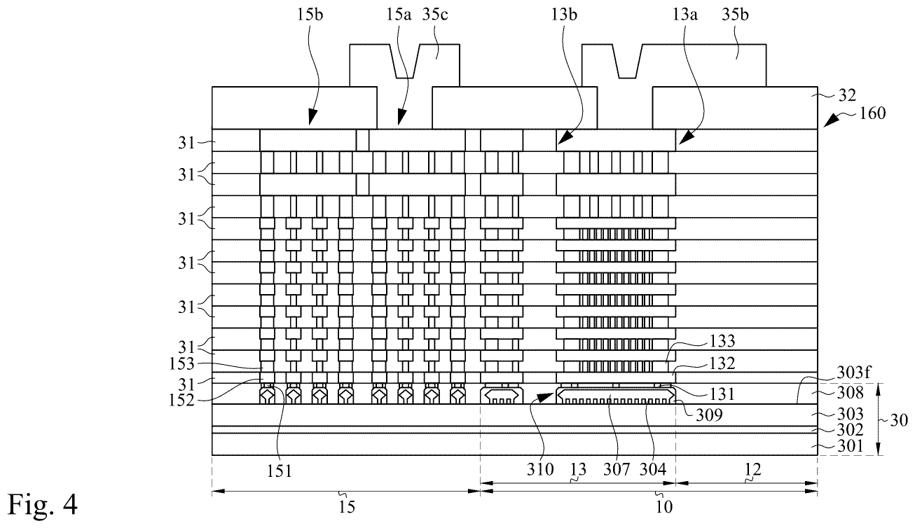

Reference is made to FIG. 4. The first passivation layer 32 can be formed over the IMD layers 31. The first passivation layer 32 can be over a topmost IMD layer 32 to protect the underlying interconnect structures and electrical devices from damage and contamination. In some embodiments, the first passivation layer 32 can further provide protection to help prevent or decrease moisture, mechanical, and radiation damage to the underlying electrical devices. In some embodiments, the first passivation layer 32 may be formed of oxides, nitrides, and/or combinations thereof. The metal pad 35a (see FIG. 1C), the metal pad 35b, and the metal pad 35c can be formed to penetrate the first passivation layer 32. The metal pad 35a can connect to the topmost metal line 112 (see FIG. 1C) in the interconnect structures 110, the metal pad 35b can connect to the topmost metal line 132 in the front-side seal ring structure 13a, and the metal pad 35c can connect to the topmost metal line 152 in the dummy pattern 15a/15b. The metal pad 35a, 35b, and/or 35c can include at least one of include aluminum, copper, copper alloy, titanium, titanium nitride, tantalum, tantalum nitride, tungsten, metal silicide, combinations thereof or other suitable materials. In some embodiments, the metal pad 35a, 35b, and/or 35c can be made of aluminum, and thus can also be interchangeable referred to as an aluminum pad.

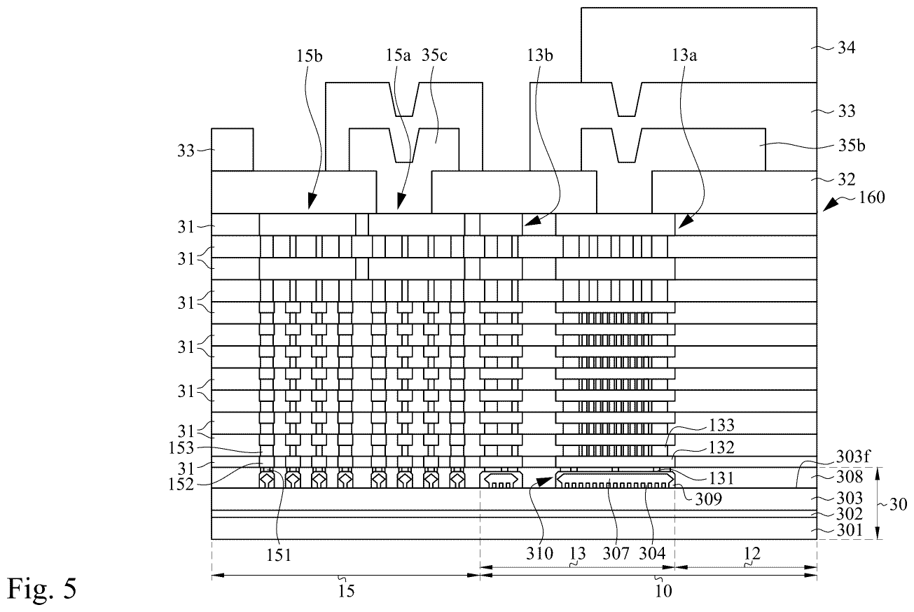

Reference is made to FIG. 5. The second passivation layer 33 can be formed over the first passivation layer 32 and the metal pads 35a, 35b, and 35c. In some embodiments, the second passivation layer 32 can be configured to protect the metal pads 35a, 35b, and 35c from being damaged. In some embodiments, the second passivation layer 33 can be configured to absorb or release thermal and/or mechanical stress caused during dicing and packaging processes. In some embodiments, the second passivation layer 33 may be formed of oxides, nitrides, and/or combinations thereof. In some embodiments, a buffer layer 34 can be formed overt the first and second passivation layers 32 and 33. In some embodiments, the buffer layer 34 can be configured to serve as a buffer for a stress mismatch resulted from differences in the coefficients of thermal expansion (CTE) of a semiconductor die and a substrate. In some embodiments, the buffer layer 34 can include at least one of polyimide (PI), benzocyclobutene (BCB), polybenzoxazole (PBO), epoxy, silicone, acrylates, nano-filled phenolic resin or other suitable material. By way of example and not limitation, the buffer layer 34 can be made of polyimide.

Reference is made to FIGS. 6A-6D. As shown in FIG. 6A, the structures of FIG. 5 can be “flipped” upside down, and the first semiconductive substrates 301 is removed. Specifically, as shown in FIG. 6B, the structures can be “flipped” upside down. Subsequently, as shown in FIGS. 6C and 6D, the substrate 301 may be thinned down (see FIG. 6C) and then removed (see FIG. 6D) in a plurality of process operations, for example, CMP, HNA, and/or TMAH etching from the back-side 303b of the second semiconductive substrate 303, which stops at the buffer layer 302. After the removal process, the buffer layer 302 can be exposed as shown in FIG. 6C. Subsequently, as shown in FIG. 6C, the buffer layer 302 can be removed.

Reference is made to FIGS. 7A-7D. The power rail 114 (see FIG. 1C) and the back-side seal ring structures 13c, 13d, 15c, and 15d can be formed. Specifically, as shown in FIG. 7B, a passivation layer 311 can be formed over the back-side 303b of the second semiconductive substrate 303. In some embodiments, the passivation layer 311 may be formed of a dielectric material, such as silicon nitride, silicon oxide, silicon oxynitride, or the like, having a high etching selectivity from the etching of the second semiconductive substrate 303. The passivation layer 311 may be formed by any suitable method, such as CVD, ALD, or the like. In some embodiments, the buffer layer 311 can be an etch stop layer.

Subsequently, as shown in FIG. 7C, the metal via 116 of the power rail 114 (see FIG. 1C) can be formed to extend through the passivation layer 311 to the buried power rail 306 formed in the circuit region 11. Additionally, the metal vias 136 and 156 (see FIGS. 7A and 7C) of the back-side seal ring structures 13c, 13d, 15c, and 15d can be formed to extend through the passivation layer 311 to the buried power rails 306 formed in the seal ring region 13 and the scribe line region 15. As shown in FIGS. 7A and 7D, the power rail 114 (see FIG. 1C) and the back-side seal ring structures 13c, 13d, 15c, and 15d can be formed over the back-side of the substrate 30 in the IMD layers 37. In FIG. 1C, the power rail 114 can include metal lines 115 and metal vias 116 in an IMD layer 37, and the metal vias 116 can connect the metal lines 114 to the substrate 30. In FIGS. 7A and 7D, the back-side seal ring structures 13c and 13d each can include metal lines 135 and metal vias 136 in the IMD layers 37 and connecting to the substrate 30. In some embodiments, the back-side seal ring structure 15c/15d can include metal lines 155 and metal vias 156 in the IMD layers 37 and connecting to the substrate 30. The back-side seal ring structures 13c, 13d, 15c, and 15d can be formed simultaneously with the construction of the power rail 114 in circuit region 11. In some embodiments, the seal ring structures 13c, 13d, 15c, and 15d can include at least one of include aluminum, carbon, cobalt, copper, copper alloy, manganese, titanium, titanium nitride, tantalum, tantalum nitride, silicon, tungsten, metal silicide, combinations thereof or other suitable materials. In some embodiments, a back-side metal process is performed on the power rail 114 and the back-side seal ring structures 13c, 13d, 15c, and 15d to form a back-side metal routing 170.

Subsequently, a die sawing process may be performed on the semiconductor structure 100. During the die sawing process, a laser beam can pass through scribe line region 15 (see FIG. 7A), so that the chip regions 10 (see FIG. 7A) can be separated from each other. The sawing path may cut through the test pads 40 (see FIG. 1A), or pass through the spacing between the test pads 40 (see FIG. 1A) and the dummy pattern 15a/15b (see FIG. 7A) and between the test pads 40 and the back-side seal ring structure 15c/15d (see FIG. 7A). Alternatively, the sawing path my cut through one or all of the dummy patterns 15a and 15b, and the back-side seal ring structures 15c and 15d.

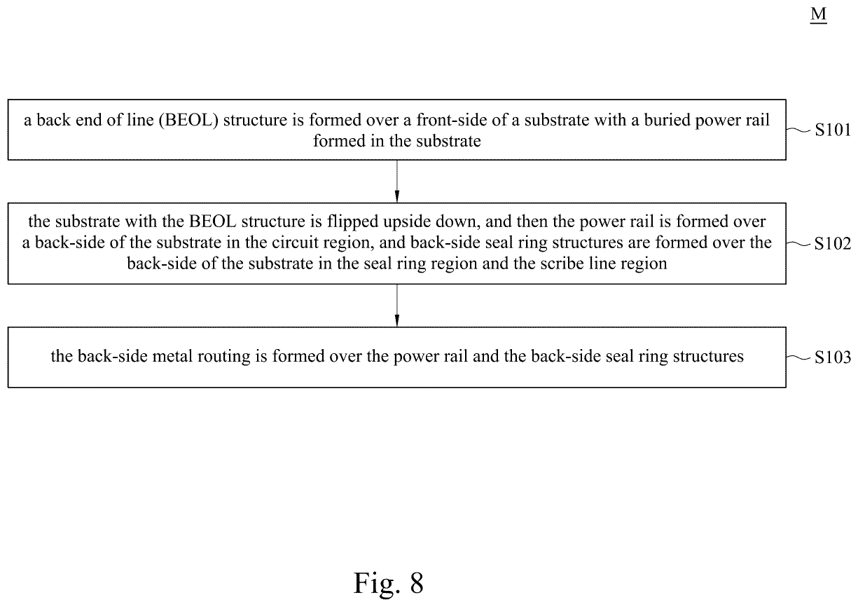

FIG. 8 is a flowchart of a method M for semiconductor manufacturing in accordance with some embodiments of the present disclosure. The method M can include a relevant part of the entire drying process. It is understood that additional operations may be provided before, during, and after the operations shown by FIG. 8, and some of the operations described below can be replaced or eliminated for additional embodiments of the method. The order of the operations/processes may be interchangeable.

The method M begins at block S101. In some embodiments of block S101 with reference to FIGS. 2A-3, the BEOL structure 160 is formed over the front-side of the substrate 30 with the buried power rail 306 formed in the substrate 30.

The method M proceeds to block S102. In some embodiments of block S102 with reference to FIG. 3, the substrate 30 with the BEOL structure 160 is flipped upside down, and then the power rail 114 is formed over the back-side of the substrate 30 in the circuit region 11, and the back-side seal ring structures 13c, 13d, 15c, and 15d are formed over the back-side of the substrate 30 in the seal ring region 13 and the scribe line region 15.

The method M proceeds to block S103. In some embodiments of block S103 with reference to FIG. 3, the back-side metal routing 170 is formed over the power rail 114 and the back-side seal ring structures 13c, 13d, 15c, and 15d.

Therefore, based on the above discussions, it can be seen that the present disclosure offers advantages. It is understood, however, that other embodiments may offer additional advantages, and not all advantages are necessarily disclosed herein, and that no particular advantage is required for all embodiments. The present disclosure in various embodiments provides a back-side seal ring structure to provide robust protection at the back-side of the semiconductor die, specifically tailored for the backside power rail. This back-side seal ring structure can ensure the integrity and reliability of power delivery from the backside of the semiconductor die, addressing a need for safeguarding against potential damages and enhancing the overall performance of the device.

In some embodiments, a method includes forming an interconnect structure over a front-side of a substrate; forming a power rail over a back-side of the substrate, wherein a footprint of the interconnect structure overlaps a footprint of the power rail on the substrate; forming a first seal ring structure over the back-side of the substrate, wherein from a top view, the first seal ring structure surrounds the power rail. In some embodiments, the method further includes forming a second seal ring structure over the back-side of the substrate, wherein from the top view, the second seal ring structure surrounds the first seal ring structure. In some embodiments, the method further includes forming a second seal ring structure over the front-side of the substrate, wherein from the top view, the second seal ring structure surrounds the interconnect structure. In some embodiments, a footprint of the first seal ring structure overlaps a footprint of the second seal ring structure on the substrate. In some embodiments, a footprint of the first seal ring structure does not overlap a footprint of the second seal ring structure on the substrate. In some embodiments, the first seal ring structure includes a back-side metal line, a plurality of first back-side vias, and a plurality of second back-side vias. The back-side metal line has a ring-shaped top view profile. The first back-side vias land on the back-side metal line and are arranged in a first ring path. The second back-side vias land on the back-side metal line and are arranged in a second ring path. In some embodiments, form the top view, the first back-side vias extend a direction, and in the direction, adjacent two of the first and second back-side vias have a distance in a range from about 0.5 to 1.5 μm. In some embodiments, form the top view, the first back-side vias extend a direction, and in the direction, adjacent two of the first back-side vias have a distance in a range from about 5 to 15 μm. In some embodiments, the substrate includes a plurality of fin structures and a plurality of epitaxial structures over the fin structures. In some embodiments, the method further includes before forming the interconnect structure, forming a buried rail laterally between the fin structures from the front-side of the substrate, wherein after forming the first seal ring structure, the first seal ring structure is connected to the buried rail.

In some embodiments, a method includes forming a front-side metal layer over a front-side of a substrate, wherein from a top view, the front-side metal layer has a ring-shaped profile surrounding a circuit region of the substrate, and the front-side metal layer is a part of a front-side seal structure; forming a plurality of first back-side metal vias over a back-side of the substrate, wherein from the top view, the first back-side metal vias are arranged in a ring path surrounding the circuit region of the substrate; forming a first back-side metal layer over the first back-side metal vias, wherein from the top view, the first back-side metal layer has a ring-shaped profile surrounding the circuit region of the substrate, and a footprint of the first back-side metal layer overlaps a footprint of the first back-side metal vias on the substrate. In some embodiments, a footprint of the first back-side metal layer overlaps a footprint of the front-side metal layer. In some embodiments, the method further includes forming a plurality of second back-side metal vias over the first back-side metal layer. In some embodiments, the method further includes forming a second back-side metal layer over the second back-side metal vias, wherein from the top view, the second back-side metal layer has a ring-shaped profile surrounding the circuit region of the substrate. In some embodiments, the method further includes forming a power rail over the back-side of the substrate in the circuit region.

In some embodiments, the semiconductor structure includes a substrate, an interconnect structure, a power rail, and first and second seal ring structures. The interconnect structure is over a front-side of the substrate within a circuit region of the substrate. The first seal ring structure is over the front-side of the substrate, wherein from a top view, the first seal ring structure surrounds the interconnect structure. The power rail is over a back-side of the substrate within the circuit region of the substrate. The second seal ring structure is over the back-side of the substrate, wherein from the top view, the second seal ring structure surrounds the power rail. In some embodiments, a footprint of the second seal ring structure overlaps a footprint of the first seal ring structure on the substrate. In some embodiments, the second seal ring structure has a same level height as the power rail. In some embodiments, the semiconductor structure further includes a third seal ring structure over the back-side of the substrate, wherein from the top view, the second seal ring structure surrounds the second seal ring structure. In some embodiments, the semiconductor structure further includes a fourth seal ring structure over the back-side of the substrate, wherein from the top view, the fourth seal ring structure surrounds the third seal ring structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming an interconnect structure over a front-side of a substrate;
forming a power rail over a back-side of the substrate, wherein a footprint of the interconnect structure overlaps a footprint of the power rail on the substrate; and
forming a first seal ring structure over the back-side of the substrate, wherein from a top view, the first seal ring structure surrounds the power rail.

2. The method of claim 1, further comprising:
forming a second seal ring structure over the back-side of the substrate, wherein from the top view, the second seal ring structure surrounds the first seal ring structure.

3. The method of claim 1, further comprising:
forming a second seal ring structure over the front-side of the substrate, wherein from the top view, the second seal ring structure surrounds the interconnect structure.

4. The method of claim 3, wherein a footprint of the first seal ring structure overlaps a footprint of the second seal ring structure on the substrate.

5. The method of claim 3, wherein a footprint of the first seal ring structure does not overlap a footprint of the second seal ring structure on the substrate.

6. The method of claim 1, wherein the first seal ring structure comprises:
a back-side metal line having a ring-shaped top view profile;
a plurality of first back-side vias landing on the back-side metal line and arranged in a first ring path; and
a plurality of second back-side vias landing on the back-side metal line and arranged in a second ring path.

7. The method of claim 6, wherein form the top view, the first back-side vias extend in a direction, and in the direction, adjacent two of the first and second back-side vias have a distance in a range from about 0.5 to 1.5 μm.

8. The method of claim 6, wherein form the top view, the first back-side vias extend in a direction, and in the direction, adjacent two of the first back-side vias have a distance in a range from about 5 to 15 μm.

9. The method of claim 1, wherein the substrate comprises:
a plurality of fin structures; and
a plurality of epitaxial structures over the fin structures.

10. The method of claim 9, further comprising:
before forming the interconnect structure, forming a buried rail laterally between the fin structures from the front-side of the substrate, wherein after forming the first seal ring structure, the first seal ring structure is connected to the buried rail.

11. A method, comprising:
forming a front-side metal layer over a front-side of a substrate, wherein from a top view, the front-side metal layer has a ring-shaped profile surrounding a circuit region of the substrate, and the front-side metal layer is a part of a front-side seal structure;
forming a plurality of first back-side metal vias over a back-side of the substrate, wherein from the top view, the first back-side metal vias are arranged in a ring path surrounding the circuit region of the substrate; and
forming a first back-side metal layer over the first back-side metal vias, wherein from the top view, the first back-side metal layer has a ring-shaped profile surrounding the circuit region of the substrate, and a footprint of the first back-side metal layer overlaps a footprint of the first back-side metal vias on the substrate.

12. The method of claim 11, wherein a footprint of the first back-side metal layer overlaps a footprint of the front-side metal layer.

13. The method of claim 11, further comprising:
forming a plurality of second back-side metal vias over the first back-side metal layer.

14. The method of claim 13, further comprising:
forming a second back-side metal layer over the second back-side metal vias, wherein from the top view, the second back-side metal layer has a ring-shaped profile surrounding the circuit region of the substrate.

15. The method of claim 11, further comprising:
forming a power rail over the back-side of the substrate in the circuit region.

16. A semiconductor structure, comprising:
a substrate;
an interconnect structure over a front-side of the substrate within a circuit region of the substrate;
a first seal ring structure over the front-side of the substrate, wherein from a top view, the first seal ring structure surrounds the interconnect structure;
a power rail over a back-side of the substrate within the circuit region of the substrate; and
a second seal ring structure over the back-side of the substrate, wherein from the top view, the second seal ring structure surrounds the power rail.

17. The semiconductor structure of claim 16, wherein a footprint of the second seal ring structure overlaps a footprint of the first seal ring structure on the substrate.

18. The semiconductor structure of claim 16, wherein the second seal ring structure has a same level height as the power rail.

19. The semiconductor structure of claim 16, further comprising:
a third seal ring structure over the back-side of the substrate, wherein from the top view, the second seal ring structure surrounds the second seal ring structure.

20. The semiconductor structure of claim 19, further comprising:
a fourth seal ring structure over the back-side of the substrate, wherein from the top view, the fourth seal ring structure surrounds the third seal ring structure.
